(19) United States
(12) Patent Application Publication
(10) Pub. No.: US 2025/0337365 A1
(43) Pub. Date: Oct. 30, 2025

(54) COMPONENT INCLUDING INDUCTOR AND COMMUNICATION DEVICE INCLUDING THE COMPONENT

(71) Applicant: Globalfoundries U.S. Inc., Malta, NY (US)

(72) Inventors: Vasudeva Reddy KUPPIREDDY, Bengaluru (IN); Indrajit Das, Bengaluru (IN); Hari Kishore Kakara, Visakhapatnam (IN); Venkata Narayana Rao Vanukuru, Bengaluru (IN)

(21) Appl. No.: 18/649,726

(22) Filed: Apr. 29, 2024

(51) Int. Cl. H03F 1/22; H03B 5/12; H03F 3/24; H04B 1/04

(52) U.S. Cl. CPC H03F 1/223; H03B 5/1228; H03F 3/245; H04B 1/0458; H03F 2200/294; H03F 2200/451; H04B 2001/0408

(57) ABSTRACT

A component of a communication device includes at least one active element, at least one passive element coupled to the at least one active element, and a first inductor surrounding the at least one active element and the at least one passive element. The first inductor is included in a redistribution structure.

### BACKGROUND

A communication device may include one or more components, each of which includes at least one active element and at least one passive element. The at least one passive element may include an inductor with a relatively high Q factor to satisfy performance requirements for the component. Since increasing the Q factor of the inductor can be realized by increasing a size of the inductor and the increased Q factor of the inductor can improve performance parameters of the component, the circuit area of the component including the inductor may be increased to improve the performance parameters of the component. That is, a tradeoff may exist between the need for reducing the circuit area of the component and that for improving the performance parameters of the component.

### SUMMARY

Embodiments of the present disclosure relate to a component and a communication device including the component. In particular, embodiments of the present disclosure relate to a component such as a low-noise amplifier (LNA), a power amplifier (PA), and a voltage-controlled oscillator (VCO), and a radio-frequency (RF) communication device including the component.

In an embodiment, a component of a communication device includes at least one active element, at least one passive element coupled to the at least one active element, and a first inductor surrounding the at least one active element and the at least one passive element. The first inductor is included in a redistribution structure.

In an embodiment, a communication device includes an antenna configured to receive a radio-frequency (RF) signal, a low-noise amplifier (LNA) configured to amplify the received RF signal, and a receiver section configured to perform demodulation, mixing, and decoding on the amplified RF signal. The LNA includes at least one active element, at least one passive element coupled to the at least one active element, and a first inductor surrounding the at least one active element and the at least one passive element. The first inductor is included in a redistribution structure of the LNA.

In an embodiment, a method for forming a component includes forming at least one active element, forming at least one passive element coupled to the at least one active element, and forming an inductor that surrounds the at least one active element and the at least one passive element. The inductor is included in a redistribution structure.

### BRIEF DESCRIPTION OF THE DRAWINGS

FIG. 1 illustrates a communication device according to an embodiment of the present disclosure.

FIG. 2 is a circuit diagram of an LNA according to an embodiment of the present disclosure.

FIG. 3A illustrates a three-dimensional view of an LNA according to an embodiment of the present disclosure. FIG. 3B illustrates a schematic cross-sectional view of a portion of the LNA according to an embodiment of the present disclosure.

FIG. 4A illustrates comparing S-parameters of an LNA with a RDL inductor according to an embodiment of the present disclosure with those of a conventional LNA with on-chip inductors. FIG. 4B illustrates comparing noise figures of the LNA with the RDL inductor according to an embodiment of the present disclosure with those of the conventional LNA. FIG. 4C illustrates comparing third-order input intercept point, output intercept point, and a figure of merit per unit circuit area of the LNA with the RDL inductor according to an embodiment of the present disclosure with those of the conventional LNA.

### DETAILED DESCRIPTION

Embodiments of the present disclosure relate to a component and a communication device including the component. In particular, embodiments of the present disclosure relate to a component such as a low-noise amplifier (LNA), a power amplifier (PA), and a voltage-controlled oscillator (VCO), and an RF communication device including the component.

A detailed description of embodiments is provided below along with accompanying figures. The scope of this disclosure is limited by the claims and encompasses numerous alternatives, modifications and equivalents. Although steps of various processes are presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured.

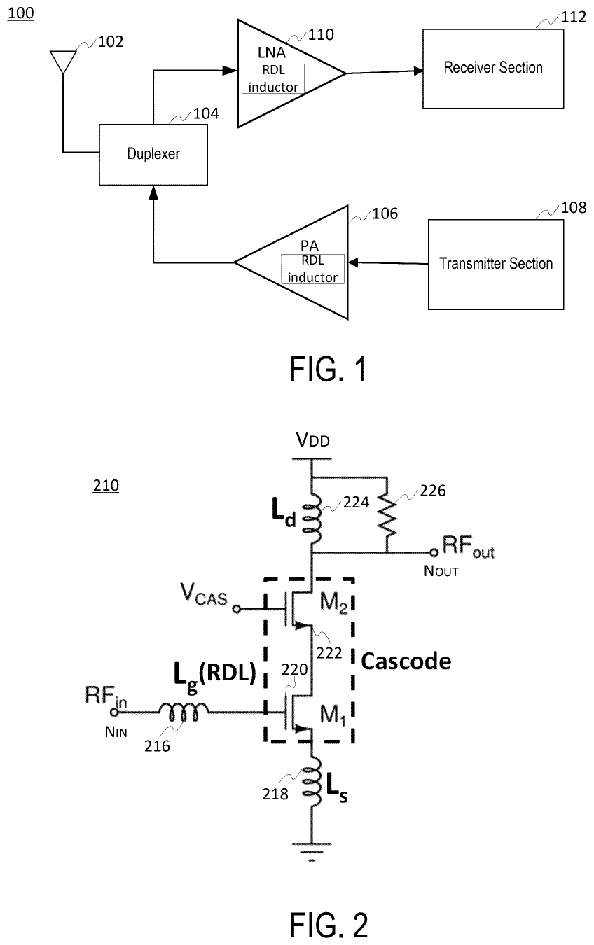

FIG. 1 illustrates a communication device 100 according to an embodiment of the present disclosure. For example, the communication device 100 in FIG. 1 is a radio-frequency (RF) transceiver.

The communication device 100 in FIG. 1 includes an antenna 102, a duplexer 104, a low-noise amplifier (LNA) 110, a receiver section 112, a power amplifier (PA) 106, and a transmitter section 108.

Upon receiving an input RF signal from the antenna 102, the duplexer 104 transmits the received RF signal to the LNA 110. The LNA 110 in FIG. 1, functioning as a first stage of a receiver front-end, amplifies the received RF signal while introducing relative low noise.

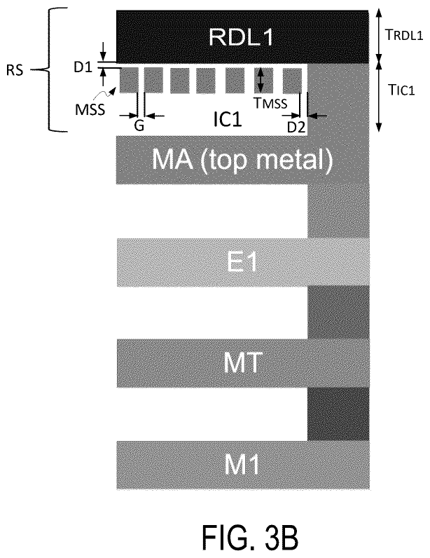

In an embodiment, the LNA 110 in FIG. 1 is implemented using a cascode structure and one or more impedance matching elements. For example, the LNA 110 may include a first transistor (e.g., a common source transistor), a second transistor (e.g., a common gate transistor), a first inductor (e.g., a gate inductor) coupled to a control terminal of the first transistor, a second inductor (e.g., a source inductor) coupled to the first transistor, and a third inductor (e.g., a drain inductor) coupled to the second transistor. The source inductor and the drain inductor may be included in a common metal layer (e.g., a top metal layer MA in FIG. 3B). The first inductor of the LNA 110 may be formed in a redistribution structure (e.g., a redistribution layer RDL) over the remaining active and passive elements (e.g., the common source transistor, the common gate transistor, the source inductor, and the drain inductor) of the LNA 110, such that the first inductor surrounds the remaining active and passive elements in a plan view. As a result, the circuit area of the LNA 110 may be significantly reduced while making performance parameters of the LNA 110 similar to or better than those of a conventional LNA with on-chip inductors.

The LNA 110 in FIG. 1 outputs the amplified RF signal to the receiver section 112. For example, the receiver section 112 may perform one or more of demodulation, mixing, and decoding operations on the amplified RF signal.

The transmitter section 108 in FIG. 1 converts a baseband signal into a transmission signal to satisfy the criteria of wireless transmissions. For example, the transmitter section 108 performs one or more of modulation, carrier mixing, and encoding operations on the baseband signal, and outputs the transmission signal to the PA 106.

The PA 106 in FIG. 1 amplifies the received transmission signal and outputs the amplified transmission signal to the duplexer 104. The duplexer 104 transmits the amplified transmission signal to the antenna 102 for RF signal transmission.

In an embodiment, the PA 106 in FIG. 1 includes at least one transistor as an amplification device, a relatively large inductor (e.g., an RF choke), at least one capacitor, and at least one inductor. For example, the RF choke may be formed in a redistribution structure (e.g., a redistribution layer RDL) over the remaining active and passive elements (e.g., the at least one transistor, the at least one capacitor, and the at least one inductor) of the PA 106, such that the RF choke surrounds the remaining active and passive elements in a plan view. As a result, the circuit area of the PA 106 may be significantly reduced while making performance parameters of the PA 106 similar to or better than those of a conventional PA with on-chip inductors.

The communication device 100 in FIG. 1 may include oscillators in both transmit and receive paths thereof. Specifically, an input of each mixer in the receiver section 112 and the transmitter section 108 in FIG. 1 may be driven by a periodic signal, thereby necessitating oscillators. In an embodiment, these oscillators include a voltage-controlled oscillator (VCO). For example, such a VCO may include an inductor in a tank circuit, at least one capacitor (e.g., a capacitor in the tank circuit), and at least one transistor (e.g., cross-coupled transistors). The inductor in the tank circuit of the VCO may be formed in a redistribution structure (e.g., a redistribution layer RDL) over the remaining active and passive elements of the VCO, such that the inductor in the tank circuit surrounds the remaining active and passive elements in a plan view. As a result, the circuit area of the VCO may be significantly reduced while making performance parameters of the VCO similar to or better than those of a conventional VCO.

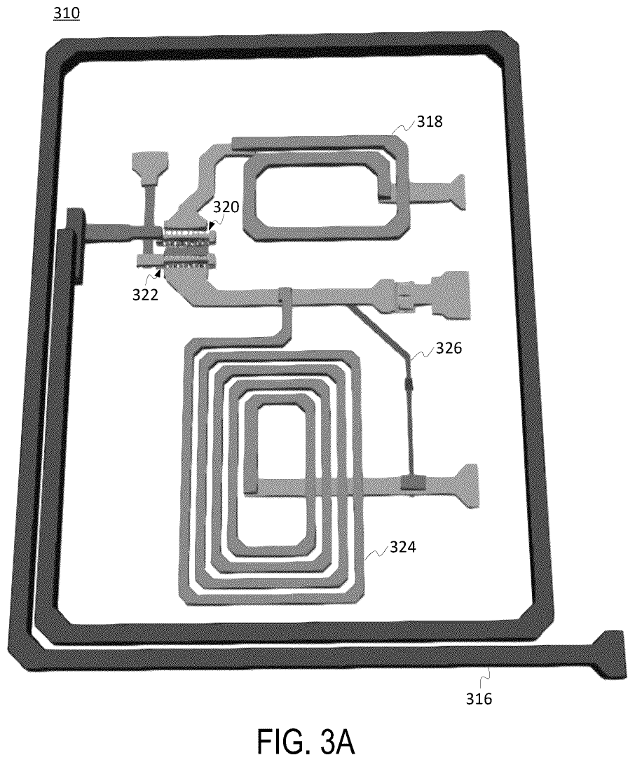

FIG. 2 is a circuit diagram of an LNA 210 according to an embodiment of the present disclosure. For example, the LNA 210 in FIG. 2 may be suitable for use as the LNA 110 in FIG. 1.

The LNA 210 in FIG. 2 includes a first transistor (e.g., a common source transistor) 220, a second transistor (e.g., a common gate transistor) 222, a first inductor (e.g., a gate inductor) 216, a second inductor (e.g., a source inductor) 218, a third inductor (e.g., a drain inductor) 224, and a resistor 226. Specifically, the LNA 210 in FIG. 2 has a cascode structure including the common source transistor 220 and the common gate transistor 222. The common source transistor 220 in FIG. 2 functions as input stage driven by an input signal (e.g., an input RF signal) RFᵢₙ, and the common gate transistor 222 functions as an output stage outputting an output signal (e.g., an output RF signal) RFₒᵤₜ.

The gate inductor 216 in FIG. 2 is coupled to an input node NIN receiving the input RF signal RFᵢₙ and a control terminal (e.g., a gate) of the common source transistor 220. The source inductor 218 in FIG. 2 is coupled to a first terminal (e.g., a source) of the common source transistor 220 and a ground.

The drain inductor 224 in FIG. 2 is coupled to a power supply V_{DD}, a second terminal (e.g., a drain) of the common gate transistor 222, and an output node N_{OUT} providing the output RF signal RFₒᵤₜ. The resistor 226 in FIG. 2 is coupled to the drain inductor 224 in parallel. The drain inductor 224 and the resistor 226 are used for output impedance matching.

Although the LNA 210 according to the embodiment shown in FIG. 2 includes N-type MOSFETs as the first and second transistors 220 and 222, embodiments of the present disclosure are not limited thereto. For example, the LNA 210 may be implemented using different types of transistors. In addition, the LNA 210 may further include one or more matching elements (e.g., a capacitor) for impedance matching in addition to the drain inductor 224 and the resistor 226.

The gate conductor 216 in FIG. 2 may be formed in a redistribution layer RDL over at least one active element (e.g., the common gate/source transistors 222 and 220) and at least one passive element (e.g., the source inductor 218, the drain inductor 224, and the resistor 226), such that the gate inductor 216 surrounds the at least one active element and the at least one passive element in a plan view, as will be described below in more detail with reference to FIGS. 3A and 3B.

FIG. 3A illustrates a three-dimensional view of an LNA 310 suitable for use as the LNA 210 in FIG. 2 according to an embodiment of the present disclosure. Some elements (e.g., dielectric layers and interconnections) of the LNA 310 have been omitted in FIG. 3A for clearly illustrating structural features of active and passive elements in the LNA 310. FIG. 3B illustrates a schematic cross-sectional view of a portion of the LNA 310 according to an embodiment of the present disclosure. Specifically, FIG. 3B illustrates a redistribution structure RS, a magnetic shielding structure MSS, a top metal layer MA, a first via layer E1, an additional metal layer MT, and a first metal layer M1.

Referring to FIGS. 3A and 3B, a second inductor (e.g., a source inductor) 318 and a third inductor (e.g., a drain inductor) 324 are formed in a common metal layer (e.g., the top metal layer MA) over a first transistor (e.g., a common source transistor) 320, a second transistor (e.g., a common gate transistor) 322, and a resistor 326. For example, when the common source transistor 320 and the common gate transistor 322 are formed in the additional metal layer MT and the first via layer E1 and the resistor 326 is formed in the first metal layer M1, the source inductor 318 and the drain inductor 324 are formed in the top metal layer MA over the common source transistor 320, the common gate transistor 322, and the resistor 326.

In an embodiment, the redistribution structure RS in FIG. 3B includes a first interconnection layer (or a first dielectric layer) IC1 and a first RDL RDL1 over the first interconnection layer IC1. Although not shown in FIG. 3B, the redistribution structure RS may include a plurality of interconnection layers and a plurality of RDLs. For example, the redistribution structure RS may include the first interconnection layer IC1, the first RDL RDL1, a second interconnection layer (not shown), and a second RDL (not shown) that are sequentially stacked over the top metal layer MA.

The first interconnection layer IC1 may be a first dielectric layer including a plurality of interconnections (e.g., vias). A thickness T_{IC1} of the first interconnection layer IC1 may be adjusted based on interference effect by magnetic fields generated from the gate inductor 316. For example, the thickness T_{IC1} of the first interconnection layer IC1 may be determined based on one or more performance parameters (e.g., S₁₂) of the LNA 310. In an embodiment, the first interconnection layer IC1 may have a thickness T_{IC1} in a range of about 50% to about 200% of a thickness T_{RDL1} of the first RDL RDL1. For example, the first interconnection layer IC1 may have the thickness T1 in a range from about 5 μm to about 20 μm, preferably, about 10 μm.

The first RDL RDL1 may be a second dielectric layer including a first inductor (e.g., a gate inductor) 316. In an embodiment, the gate inductor 316 is disposed over the second inductor 318 and the third inductor 324. For example, when the source inductor 318 and the drain inductor 324 are formed in the top metal layer MA, the gate inductor 316 is formed in the first RDL RDL1 over the top metal layer MA.

The first RDL RDL1 may be formed by first forming the second dielectric layer over the first interconnection layer IC1. For example, the second dielectric layer may be formed by various deposition methods (e.g., spin coating, lamination, CVD, etc.). Then, the second dielectric layer may be patterned to form openings that expose the interconnections (e.g., vias) of the first interconnection layer IC1. For example, a patterned mask may be formed over the second dielectric layer, a developing process may be performed to form the openings, and the patterned mask may be removed. Subsequently, a seed layer may be formed over the patterned second dielectric layer and in the openings. For example, the seed layer may be formed using various deposition methods (e.g., PVD). A photoresist mask is formed on the seed layer and then patterned to form openings that expose desired portions of the seed layer. A conductive material is formed in the openings of the photoresist mask on the exposed portions of the seed layer. For example, the conductive material may be formed by plating (e.g., electroplating or electroless plating). The photoresist mask and undesired portions of the seed layer on which the conductive material is not formed are removed. For example, the photoresist mask may be removed using an ashing or stripping process, and the undesired portions of the seed layer may be removed using an etching process (e.g., wet or dry etching). The remaining portions of the seed layer, the conductive material, and the second dielectric layer form the first RDL RDL1.

When the redistribution RS includes the first interconnection layer IC1, the first RDL RDL1, a second interconnection layer (not shown), and a second RDL (not shown), the remaining layers (e.g., the first interconnection layer IC1, the second interconnection layer, and the second RDL) may be formed using processes similar to the above-described processes of forming the first RDL RDL1.

The magnetic shielding structure MSS in FIG. 3B is disposed under the first RDL layer RDL1 to further reduce interference by magnetic fields generated from the gate inductor 316 formed in the first RDL layer RDL1. In an embodiment, the magnetic shielding structure MSS may be disposed to overlap the gate inductor 316 in the first RDL layer RDL1 in a plan view. The magnetic shield structure MSS in FIG. 3B includes a plurality of lines embedded in the first interconnection layer IC1 and each of the plurality of lines extends in the same direction(s) as overlapping portion(s) of the gate inductor 316. Each of the plurality of lines may have a thickness T_{MSS} in a range of about 5% to about 10% of the thickness T_{IC1} of the first interconnection layer IC1. For example, the thickness T_{MSS} may be in a range of about 0.5 μm to about 1 μm. The plurality of lines may be spaced apart from a bottom surface of the gate inductor 316 in the first RDL RDL1 by a given distance D1 (e.g., about 0.5 μm to about 5 μm) and spaced apart from each other by a given interval G (e.g., about 0.2 μm to about 2 μm). One of the plurality of lines may be spaced apart from an adjacent interconnection (e.g., a via) in the first interconnection layer IC1 by a given distance D2 (e.g., about 0.5 μm to about 5 μm).

In an embodiment, the magnetic shielding structure MSS in FIG. 3B includes one or more materials suitable for high frequency magnetic shielding. For example, the magnetic shielding structure MSS may include materials with relatively high electrical conductivity such as aluminum or copper.

The LNA 310 according to the embodiment shown in FIG. 3B includes the magnetic shielding structure MSS to further reduce interference by magnetic fields generated from the gate inductor 316 formed in the first RDL layer RDL1, thereby further improving the performance of the LNA 310. However, embodiments of the present disclosure are not limited thereto. In some embodiments, the magnetic shielding structure MSS may be omitted to simplify fabrication processes of the LNA 310 and increase the production yield.

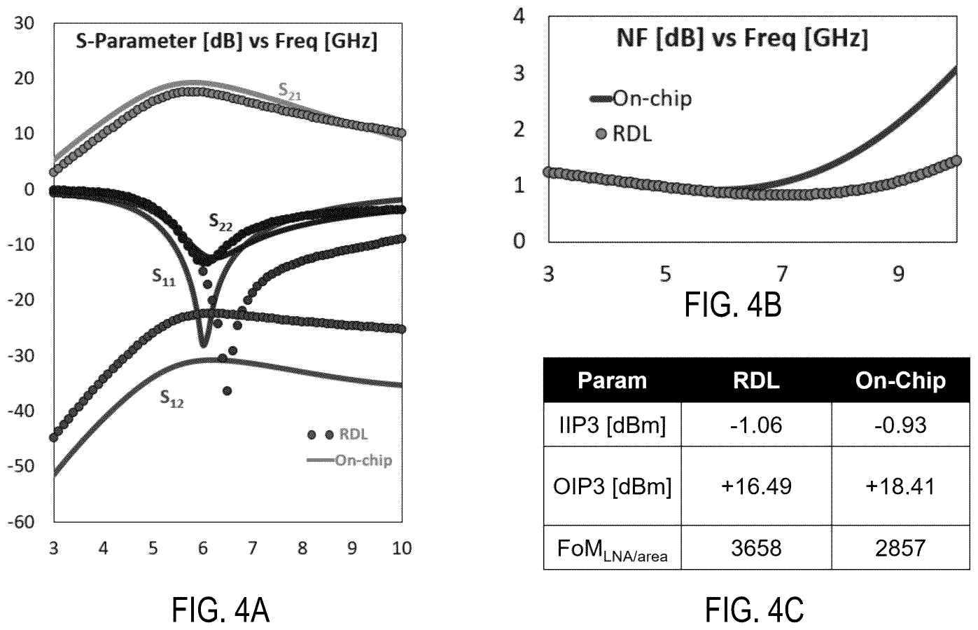

In the embodiment of FIGS. 3A and 3B, the first RDL RDL1 is formed to include the gate inductor 316. Specifically, the gate inductor 316 is disposed over at least one active element (e.g., the common source/gate transistors 320 and 322) and at least one passive element (e.g., the source inductor 318, the drain inductor 324, and the resistor 326), such that the gate inductor 316 surrounds the at least one active element and the at least one passive element in a plan view. For example, the gate conductor 316 may be disposed over all of the remaining active and passive elements 318, 320, 322, 324, and 326 of the LNA 310, such that the active and passive elements 318, 320, 322, 324, and 326 are within an inner boundary of the gate inductor 316 when the gate conductor 316 and the remaining elements 318, 320, 322, 324, and 326 are projected onto a horizontal plane suspended above and parallel to a top surface of the LNA 310. As a result, the LNA 310 according to an embodiment of the present disclosure significantly reduces its circuit area while ensuring desirable performance characteristics (e.g., desirable Q factor and inductance of the gate inductor 316), compared to the circuit area of a conventional LNA with on-chip inductors. For example, the LNA 310 according to an embodiment of the present disclosure may have the circuit area less than 50% of that of a conventional LNA including a gate inductor, a source inductor, and a drain inductor that are formed in the same layer as the on-chip inductors. In addition, the LNA 310 according to an embodiment of the present disclosure exhibit performance parameters similar to or better than those of the conventional LNA, as will be described below in more detail with reference to FIGS. 4A and 4B.

FIG. 4A illustrates comparison of S-parameters of an LNA (e.g., the LNA in FIG. 3A) with a RDL inductor (e.g., the gate inductor 316 in FIG. 3A) according to an embodiment of the present disclosure with those of a conventional LNA with on-chip inductors. FIG. 4B illustrates comparing noise figures of the LNA with the RDL inductor according to an embodiment of the present disclosure with those of the conventional LNA. FIG. 4C illustrates comparing third-order input intercept point, output intercept point, and a figure of merit per unit circuit area of the LNA with the RDL inductor according to an embodiment of the present disclosure with those of the conventional LNA.

As shown in FIG. 4A, the S-parameters of the LNA according to an embodiment of the present disclosure show characteristics similar to those of the conventional LNA. Specifically, transmission coefficient S₂₁ and reflection coefficient S₂₂ of the LNA according to an embodiment of the present disclosure have values similar to those of the conventional LNA over a wide range of operating frequency, indicating similar gain and loss, respectively. For example, transmission coefficients S₂₁ at 5.9 GHz of the LNA according to an embodiment of the present disclosure and the conventional LNA are 17.55 dB and 19.34 dB, respectively, resulting in a relatively small difference (i.e., 1.79 dB) in gain. The LNA according to the embodiment in FIGS. 4A-4C has a circuit area of about 47% of that of the conventional LNA. As a result, the LNA according to an embodiment of the present disclosure has a significantly reduced circuit area compared to the conventional LNA while keeping the S-parameters S₂₁ and S₂₂ similar to those of the conventional LNA.

As shown in FIG. 4B, the noise figures of the LNA according to an embodiment of the present disclosure exhibit better characteristics compared to those of the conventional LNA. For example, the noise figures at 5.9 GHz of the LNA according to an embodiment of the present disclosure and the conventional LNA are 0.87 dB and 0.91 dB, respectively, indicating an improvement in noise figure of the LNA according to an embodiment of the present disclosure compared to the conventional LNA.

Other parameters to quantify and evaluate performance of the LNA according to an embodiment of the present disclosure exhibit similar or better characteristics compared to those of the conventional LNA. For example, referring to FIG. 4C, the third-order input intercept points IIP3 at 5.9 GHz of the LNA according to an embodiment of the present disclosure and the conventional LNA are-1.06 dBm and −0.93 dBm, respectively. The third-order output intercept points OIP3 at 5.9 GHz of the LNA according to an embodiment of the present disclosure and the conventional LNA are 16.49 dBm and 18.41 dBm, respectively.

In particular, a figure of merit per unit circuit area FOM_{LNA/area} of an LNA may be defined as follows:

$$F O {M}_{LNA / area} = \frac{( G \times IIP 3 \times f )}{( F - 1 ) {P}_{DC}} \times \frac{1}{Area ( {mm}^{2} )} ,$$

where G denotes gain, IIP3 denotes the third-order input intercept point, f denotes frequency, F denotes noise factor, P_{DC} denotes DC power in a transistor, and area is the circuit area in mm². The figure of merit per unit circuit unit circuit area FOM_{LNA/area} of the LNA according to according to an embodiment of the present disclosure indicates a significant improvement (e.g., about 30%) compared to that of the conventional LNA at a specific frequency (e.g., 5.9 GHz).

As described above, a component (e.g., the LNA 110 in FIG. 1, the PA 106 in FIG. 1, and an VCO) in a communication device (e.g., the communication device 100 in FIG. 1) according to an embodiment of the present disclosure includes an inductor (e.g., the gate inductor 316 in FIG. 3) is disposed in a redistribution structure (e.g., the first RDL RDL1 in FIG. 3B) over at least one active element (e.g., the common source/gate transistors 320 and 322) and at least one passive element (e.g., the source inductor 318, the drain inductor 324, and the resistor 326). The inductor of the component surrounds the at least one active element and the at least one passive element in a plan view. As a result, such a component according to an embodiment of the present disclosure saves the circuit area compared to a conventional component, while exhibiting similar or better performance characteristics compared to the conventional component.

Aspects of the present disclosure have been described in conjunction with the specific embodiments thereof that are proposed as examples. Numerous alternatives, modifications, and variations to the embodiments as set forth herein may be made without departing from the scope of the claims set forth below. Accordingly, embodiments as set forth herein are intended to be illustrative and not limiting.

1. A component comprising:
at least one active element;
at least one passive element coupled to the at least one active element; and
a first inductor surrounding the at least one active element and the at least one passive element,
wherein the first inductor is included in a redistribution structure.

2. The component of claim 1, wherein the first inductor is over the at least one active element and the at least one passive element, and surrounds the at least one active element and the at least one passive element in a plan view.

3. The component of claim 2, further comprising a magnetic shielding structure under the first inductor.

4. The component of claim 3, wherein the magnetic shielding structure overlaps the first inductor.

5. The component of claim 4, wherein the magnetic shielding structure includes a plurality of lines embedded in a dielectric layer, each of the plurality of lines having a thickness in a range of about 5% to about 10% of a thickness of the dielectric layer.

6. The component of claim 2, wherein the redistribution structure includes a dielectric layer and a redistribution layer (RDL), the RDL including the first inductor, and a thickness of the dielectric layer is in a range of about 50% to about 200% of a thickness of the RDL.

7. The component of claim 2, wherein the component is a low-noise amplifier (LNA), the at least one active element includes a first transistor and a second transistor coupled to the first transistor, the first inductor is coupled to the first transistor, and the at least one passive element includes a second inductor coupled to the first transistor and a third inductor coupled to the second transistor.

8. The component of claim 7, wherein the first inductor is coupled to a control terminal of the first transistor, the second inductor is coupled to a first terminal of the first transistor, the third inductor is coupled to a second terminal of the second transistor, and the second and third inductors are included in a common metal layer, and
wherein a second terminal of the first transistor is coupled to a first terminal of the second transistor.

9. The component of claim 8, wherein the common metal layer including the second and third inductors is over the first transistor and the second transistor.

10. The component of claim 8, further comprising:
an input node configured to receive an input signal and coupled to the first inductor; and
an output node configured to provide an output signal and coupled to the second terminal of the second transistor.

11. The component of claim 2, wherein the component is a power amplifier (PA), the first inductor is a radio-frequency (RF) choke, the at least one active element includes at least one transistor, and the at least one passive element includes at least one capacitor and at least one second inductor.

12. The component of claim 2, wherein the component is a voltage-controlled oscillator (VCO), the first inductor is an inductor of a tank circuit of the VCO, the at least one active element includes at least one transistor, and the at least one passive element includes at least one capacitor.

13. A communication device, comprising:
an antenna configured to receive a radio-frequency (RF) signal;
a low-noise amplifier (LNA) configured to amplify the received RF signal, the LNA including at least one active element, at least one passive element coupled to the at least one active element, and a first inductor surrounding the at least one active element and the at least one passive element; and
a receiver section configured to perform one or more of demodulation, mixing, and decoding operations on the amplified RF signal,
wherein the first inductor is included in a redistribution structure of the LNA.

14. The communication device of claim 13, wherein the first inductor is over the at least one active element and the at least one passive element, and surrounds the at least one active element and the at least one passive element in a plan view.

15. The communication device of claim 14, further comprising a magnetic shielding structure under the first inductor.

16. The communication device of claim 15, wherein the magnetic shielding structure overlaps the first inductor.

17. The communication device of claim 14, wherein the at least one active element includes a first transistor and a second transistor coupled to the first transistor, the first inductor is coupled to the first transistor, and the at least one passive element includes a second inductor coupled to the first transistor and a third inductor coupled to the second transistor.

18. The communication device of claim 14, further comprising:
a transmitter section configured to perform one or more of modulation, carrier mixing, and encoding operations on a baseband signal to output a transmission signal;
a power amplifier (PA) configured to amplify the transmission signal, the PA including at least one amplification device, at least one capacitor, at least one inductor, and an RF choke; and
a duplexer configured to transmit the amplified transmission signal to the antenna and to transmit the received RF signal to the LNA,
wherein the RF choke is over the at least one amplification device, the at least one capacitor, and the at least one inductor, the RF choke surrounds the at least one amplification device, the at least one capacitor, and the at least one inductor in the plan view, and the RF choke is included in a redistribution structure of the PA.

19. A method for forming a component, comprising:
forming at least one active element;
forming at least one passive element coupled to the at least one active element; and
forming an inductor that surrounds the at least one active element and the at least one passive element,
wherein the inductor is included in a redistribution structure.

20. The method of claim 19, wherein the first inductor is formed over the at least one active element and the at least one passive element to surround the at least one active element and the at least one passive element in a plan view.
